(19) United States
(12) Patent Application Publication
(10) Pub. No.: US 2007/0204906 A1
(43) Pub. Date: Sep. 6, 2007

(54) Dye Sensitization Solar Cell and Manufacturing Method Thereof

(76) Inventors: Hideo Abe, Kanagawa (JP); Yasuhito Tanaka, Kanagawa (JP); Ariyoshi Ogasawara, Kanagawa (JP)

Correspondence Address: REED SMITH LLP, 3110 FAIRVIEW PARK DRIVE, SUITE 1400, FALLS CHURCH, VA, 22042, US

(21) Appl. No.: 11/596,112

(22) PCT Filed: May 26, 2005
(86) PCT No.: PCT/JP05/09677

§ 371 Date: Nov. 9, 2006

(30) Foreign Application Priority Data
Jun. 8, 2004 (JP) 2004-198688
Mar. 29, 2005 (JP) PCT/JP05/05806

(51) Int. Cl. H01L 31/00

(52) U.S. Cl. 136/263

(57) ABSTRACT

A dye-sensitized solar cell and a method for manufacturing the same. By maintaining a constant interval between two substrates and controlling the amount and flowability of electrolyte retained between the substrates, superior reproducibility and stable performance can be obtained. On the surface of at least one transparent substrate, a transparent conductive film and a dye-sensitized semiconductor electrode are formed. The two substrates are then stacked with an electrolyte sealed between them. Between the two substrates, a member composed of two or more wire rods and formed in the shape of a mesh is disposed, functioning as an electrode.

### TECHNICAL FIELD

The present invention relates to a dye-sensitized solar cell in which light energy is directly converted into electric energy, and a method for manufacturing such dye-sensitized solar cell.

### BACKGROUND ART

The dye-sensitized solar cell published by Grätzel et al. in 1991 operates on a different mechanism from that of solar cells based on the p-n junction of silicon semiconductor. It has high conversion efficiency, and manufacturing cost is low. The Grätzel solar cell has an electrolyte sealed therein; hence the name dye-sensitized solar cell.

This solar cell, as shown in FIG. 4, includes a transparent substrate 1 on one side of which a transparent conductive film 7 is formed, and a conductive substrate 5 on which a semiconductor electrode (dye-sensitized semiconductor electrode 4) carrying a sensitizing dye is formed. The two substrates are stacked one upon the other with an electrolyte contained therebetween, and the assembly is sealed with resin. A porous titanium oxide film is provided on the surface of the conductive substrate and is coated with a sensitizing dye that can efficiently absorbs solar light, such as ruthenium complex. The porous titanium oxide film is used as a dye-sensitized semiconductor electrode, whereby an electron excited by light is injected into the titanium oxide and a flow of electric current can be caused. This type of solar cells requires electrolyte for the exchange of electrons, and generally iodine electrolyte is used for this purpose.

Patent Document 1: JP Patent Publication (Kokoku) No. 8-15097 B (1996)

Patent Document 2: JP Patent Publication (Kokai) No. 2000-173680 A

### DISCLOSURE OF THE INVENTION

Problems to be Solved by the Invention

In the conventional dye-sensitized solar cell shown in FIG. 4, the electrolyte is only sealed with a thick coating of resin at the peripheral portion (near the cross section), which is then cured. However, the amount of electrolyte may vary due to different intervals between the two substrates from one solar cell to another, or even within each solar cell. As a result, there have been problems in terms of reproducibility and safety due to the leakage of the electrolyte that may be caused when the solar cell is inclined, for example.

Furthermore, the surface irregularities of the porous titanium oxide film used as the dye-sensitized semiconductor electrode vary depending on the coating method used, the particle diameter, or the thickness of the film. Should a projecting portion of the film come into contact with the conductive film on the opposite substrate, the dye-sensitized semiconductor electrode will be electrically in contact with the conductive film, bypassing the electrolyte. This would prevent the sufficient exchange of electrons, and lead to decrease in efficiency and destabilization of performance of the solar cell.

In view of these problems, it is an object of the present invention to provide a dye-sensitized solar cell in which a constant interval is maintained between the two substrates and the amount and flowability of the electrolyte retained between the substrates is controlled, whereby excellent reproducibility and stable performance can be provided. It is another object of the invention to provide a method for manufacturing such solar cell.

Means for Solving the Problems

As a result of intensive research and analysis, the inventors found that the aforementioned objects can be achieved by placing wire rods woven in the form of a mesh between the substrates of the dye-sensitized solar cell so as to retain the electrolyte thereby.

Specifically, the invention provides a dye-sensitized solar cell comprising two transparent substrates, of which at least one has a transparent conductive film and a dye-sensitized semiconductor electrode formed on the surface thereof, wherein the substrates are stacked with an electrolyte sealed therebetween, wherein a member composed of two or more wire rods woven in the shape of a mesh is disposed between the two substrates, the member functioning as an electrode.

In the dye-sensitized solar cell of the invention, the wire rods are electrically conductive. Alternatively, the wire rods may be insulating and have an electrically conductive film formed on the surface of one or both sides thereof.

In the dye-sensitized solar cell of the invention, the thickness of the wire rods is greater than the height of the irregularities on the surface of the substrate on which the transparent conductive film and the dye-sensitized semiconductor electrode are formed.

In the dye-sensitized solar cell of the invention, the substrate on which neither the transparent conductive film nor the dye-sensitized semiconductor electrode is formed is insulating.

### EFFECTS OF THE INVENTION

As described above, in accordance with the present invention, by disposing the electrolyte retaining/electrode member between the two substrates, the amount of the electrolyte retained between them can be stabilized and its flowability can be restricted. Furthermore, the dye-sensitized semiconductor electrode and the conductive film are prevented from coming into contact with each other bypassing the electrolyte. Thus, a dye-sensitized solar cell is provided that is highly efficient and offers excellent reproducibility and stable performance.

### BRIEF DESCRIPTION OF THE DRAWINGS

FIG. 1 shows a schematic cross section of an example of the dye-sensitized solar cell according to the invention.

FIG. 2 shows a process flow of an example of a process for manufacturing the dye-sensitized solar cell of the invention.

FIG. 3 shows an example of the structure of an electrolyte retaining/electrode member in the dye-sensitized solar cell of the invention.

FIG. 4 shows a schematic cross section of an example of a conventional dye-sensitized solar cell.

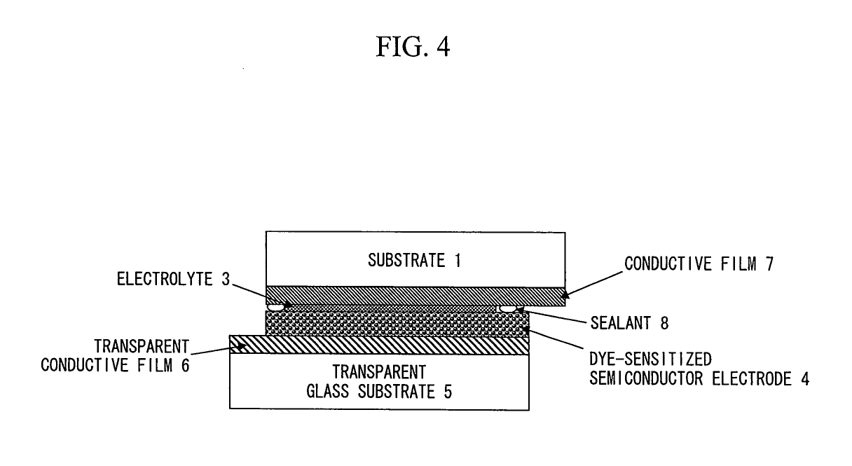

### EXPLANATION OF REFERENCE NUMERALS

1 substrate
2 electrolyte retaining/electrode member
3 electrolyte
4 dye-sensitized semiconductor electrode
5 transparent glass substrate
6 transparent conductive film
7 conductive film
8 sealant

### BEST MODE FOR CARRYING OUT THE INVENTION

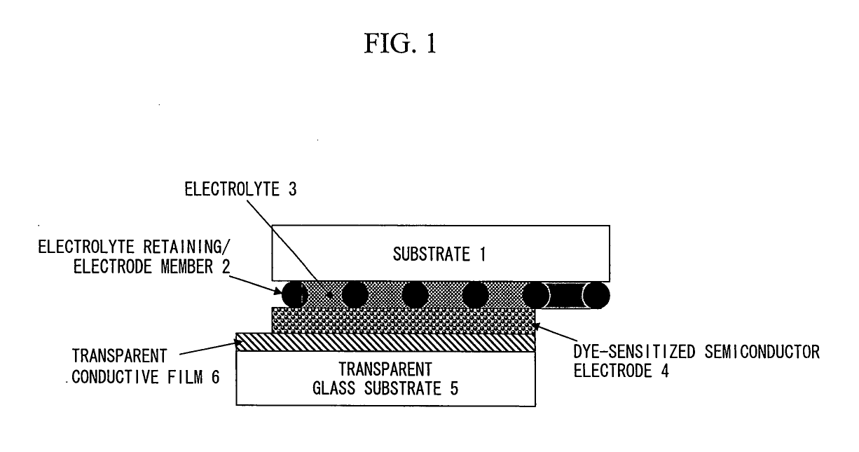

In the following, the dye-sensitized solar cell according to an embodiment of the invention will be described with reference to the drawings. FIG. 1 shows a schematic cross section of the dye-sensitized solar cell according to the present embodiment.

Referring to FIG. 1, the dye-sensitized solar cell according to the present embodiment includes a substrate 1 and a transparent glass substrate 5 on which a dye-sensitized semiconductor electrode 4 and a transparent conductive film 6 are formed. Between these substrates, a mesh-like electrolyte retaining/electrode member 2 is disposed in which electrolyte 3 is contained. While the substrates are sealed by applying a sealant to the sides thereof, such sealing is not shown in the drawings.

The substrate 1 may be comprised of an insulating glass substrate, a ceramic substrate, a substrate made of conducting material such as metal or carbon, or a metal plate, for example. The transparent glass substrate 5 may be replaced by a transparent plastic substrate or the like. The dye-sensitized semiconductor electrode 4 may be comprised of but is not limited to titanium oxide, tantalum oxide, niobium oxide, or zirconium oxide. The transparent conductive film 6 may be comprised of but is not limited to ITO (tin-containing indium oxide), tin oxide, or zinc oxide. It may also be comprised of a film of platinum, metal, or carbon having such a film thickness that the film causes no decrease in transmittance. The sealant is not particularly limited as long as its hardness changes depending on temperature and is capable of sealing the space between the substrates.

The electrolyte retaining/electrode member 2 is comprised of a plurality of wire rods woven in the form of a mesh. The wire rods may be woven by flat weaving, twilled weaving, plain dutch weaving, or twilled dutch weaving, for example. Each wire rod may consist of a twisted wire rod composed of two or more wire rods. The shape of the wire rods of the electrolyte retaining/electrode member 2 may be but is not limited to rectangular-cylindrical or columnar, for example. The thickness of the electrolyte retaining/electrode member 2 only needs to be greater than the irregularities on the surface of the conductive substrate or the dye-sensitized semiconductor electrode 4. Generally, the thickness is on the order of several μm to 1 mm, and more preferably on the order of several dozen μm to several hundred μm. The pitch of the mesh of the electrolyte retaining/electrode member 2 or the diameter of its wire rods may be selected as desired as long as the electrolyte can permeate the mesh or the space between the wire rods so as to restrict the flow of electrolyte.

The material of the wire rods of the electrolyte retaining/electrode member 2 may be but is not limited to metal conducting material such as stainless steel, Al, or Ni. The wire rods may also be made of glass, ceramics such as alumina, or other insulating material composed of a polymer such as nylon or polyimide, on the surface of one side of which Pt, carbon, or metal such as Al or Ni is coated by evaporation or plating. Thus, any material may be used as long as it does not dissolve in the electrolyte used or reject the electrolyte (i.e., not water-repellent).

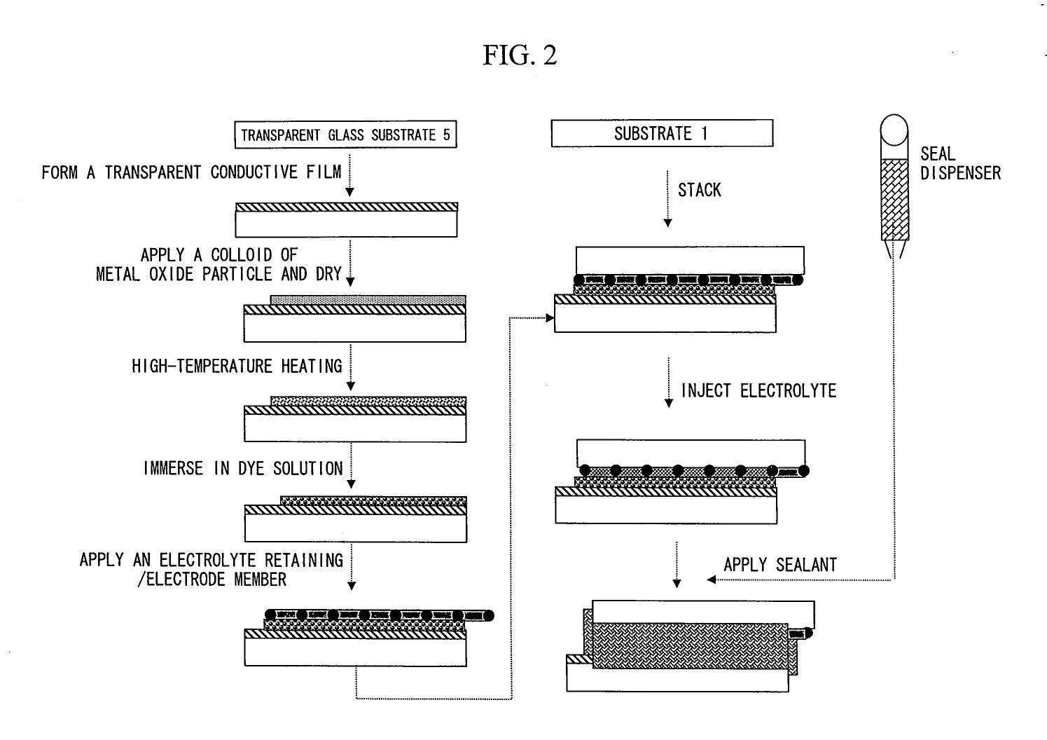

Referring to FIG. 2, a method for manufacturing the dye-sensitized solar cell according to the embodiment is described.

First, as the transparent glass substrate 5, a transparent glass substrate or plastic substrate is prepared. On this substrate, a transparent conductive film 6 is formed that is comprised of ITO (tin-containing indium oxide), tin oxide, or zinc oxide, or a film of metal or carbon, such as platinum or Ti, for example, having such a film thickness that the film causes no decrease in transmittance.

The surface of the transparent conductive film 6 is then coated with a colloidal solution by printing or the like. The solution contains a particle of metal oxide, such as titanium oxide , tantalum oxide, niobium oxide, or zirconium oxide, and a small amount of organic polymer. After allowing it to dry naturally, the film is heated at 500° C. so as to evaporate the organic polymer, whereby fine pores are formed in the surface on which the metal oxide particle was coated. The height of the surface irregularities is then measured with a surface shape evaluating device, such as Alpha-Step. The porous metal oxide film thus formed on the surface of the transparent conductive film 6 is then immersed in a solution of sensitizing dye, whereby the sensitizing dye becomes adsorbed on the surface and a dye-sensitized semiconductor electrode 4 is formed.

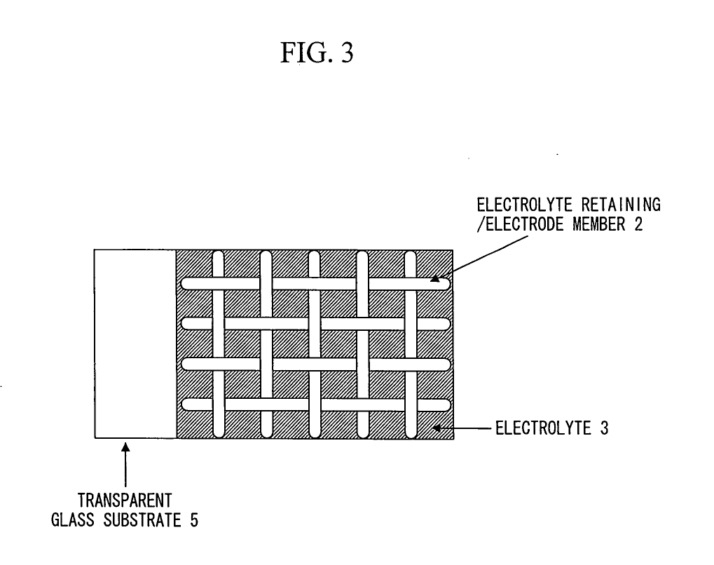

On the dye-sensitized semiconductor electrode 4 thus formed on the transparent conductive substrate 5, the mesh-woven electrolyte retaining/electrode member 2 is disposed. FIG. 3 shows a top plan view of the electrolyte retaining/electrode member 2 thus disposed. In this case, the electrolyte retaining/electrode member 2 prepared is selected such that it is thicker than the height of the surface irregularities of the dye-sensitized semiconductor electrode 4 as measured above.

Thereafter, the substrate 1 is placed from above so as to cover the electrolyte retaining/electrode member 2, iodine electrolyte is injected between the substrates, and a sealant is applied to areas between the substrates. It is noted that the electrolyte 3 is not limited to iodine electrolyte but may be any organic electrolyte that contains oxidizing and reducing species.

### EXAMPLES

### Example 1

A dye-sensitized solar cell according to the above-described embodiment was made by the following process. Two glass substrates measuring 2×3 cm and having a thickness of 2.8 mm were prepared. On one of the substrates, an ITO film as the transparent conductive film 6 was formed by sputtering to a thickness of 200 nm. The height of the surface irregularities was substantially not more than 1 μm. The substrate 5, on which the transparent conductive film 6 was formed, was then masked with tape and coated. Thereafter, a paste prepared by well mixing photocatalytic titanium oxide having a particle diameter of about 20 nm with water, polyethylene glycol, and nitric acid was applied to the substrate by printing.

The substrate was then heated in the atmosphere at 500° C. for 30 minutes, followed by cooling, thereby forming a titania film having an average thickness of approximately 10 μm. The height of the surface irregularities was substantially not more than 30 μm. For this reason, it was decided that the electrolyte retaining/electrode member 2 used should have a thickness of 30 μm or more. The thus formed titania film was further immersed in an acetonitrile solution of ruthenium complex. As a result, the ruthenium complex, which is the sensitizing dye, became adsorbed on and thus coated the titanium oxide particles, of which the film was composed, whereby a dye-sensitized semiconductor electrode 4 was formed.

For the electrolyte retaining/electrode member 2, wires were made from twisted wire rods, each made of three stainless steel wire rods having a diameter of 16 μm. Using these wires, a mesh with a pitch of substantially 100 μm was prepared. The thickness was about 50 μm. The electrolyte retaining/electrode member 2 was placed between the substrate 5, on which the dye-sensitized semiconductor electrode 4 was formed, and the other substrate 1, and then the iodine electrolyte 3 was injected between the substrates.

The iodine electrolyte 3 was prepared by dissolving 0.5M lithium iodide and 0.05M iodine in a mixture solution of 3-methoxypropionitrile and acetonitrile. Further, using a dispenser, a sealant was applied to areas between the substrate for sealing purposes, whereby a dye-sensitized solar cell was prepared.

### Example 2

In the present example, a dye-sensitized solar cell was made in the same way as in Example 1, with the exception that a film of Pt with a thickness of approximately 10 nm was formed by ion beam assisted deposition on one side of the electrolyte retaining/electrode member used in Example 1. Ten of such cells were made in the present example.

### Example 3

In the present example, a dye-sensitized solar cell was made in the same way as in Example 1 with the exception that a film of Pt with a thickness of approximately 10 nm was formed by ion beam assisted deposition on both sides of the electrolyte retaining/electrode member used in Example 1. Ten of such cells were made in the present example.

### Example 4

In the present example, the electrolyte retaining/electrode member 2 was made in the form of a mesh having a thickness of approximately 100 μm and a pitch of approximately 100 μm, using nylon wire rods of a diameter of 16 μm. One side of the electrolyte retaining/electrode member 2 was coated with a film of Pt by ion beam assisted deposition to a thickness of approximately 10 nm. Using such electrolyte retaining/electrode member 2, a dye-sensitized solar cell was made in the same way as in Example 1. In the present example, 10 of such cells were made.

### Comparative Example

As a comparative example, 10 dye-sensitized solar cell were made in the same way as in Example 1 with the exception that the electrolyte retaining/electrode member 2 was not used.

Result of Comparison

The dye-sensitized solar cells according to Examples 1 to 4 were irradiated with xenon lamp and their electromotive force was measured. In the cells of the Comparative Example, the short-circuit current per 1 cm² at 100 mW was 5 to 15 mA and the open voltage was 0.57 to 0.65V. In the cells of Example 1, the short-circuit current per 1 cm² was about 15 mA and the open voltage was about 0.6V. In the cells of Example 2, the short-circuit current per 1 cm² was about 20 mA and the open voltage was about 0.65V. In the cells of Example 3, the short-circuit current per 1 cm² was about 25 mA and the open voltage was about 0.65V. In the cells of Example 4, the short-circuit current per 1 cm² was about 8 mA and the open voltage was about 0.60V for all of the ten cells.

Thus, it was confirmed that the dye-sensitized solar cell according to the invention offers excellent reproducibility and stable performance.

While the dye-sensitized solar cell and method for manufacturing the same according to the invention have been described with reference to specific embodiments, the invention is not limited to such embodiments. It should be obvious to those skilled in the art that various changes or improvements can be made to the above-described embodiments or other embodiments of the invention in terms of structure or function without departing from the gist of the invention.

1. A dye-sensitized solar cell comprising two substrates, of which at least one, which is transparent, has a transparent conductive film and a dye-sensitized semiconductor electrode formed on the surface thereof, wherein the substrates are stacked with an electrolyte sealed therebetween,
wherein a member composed of two or more wire rods woven in the shape of a mesh is disposed between the two substrates, the member functioning as an electrode.

2. The dye-sensitized solar cell according to claim 1, wherein the wire rods are electrically conductive.

3. The dye-sensitized solar cell according to claim 1, wherein the wire rods are insulating and have an electrically conductive film formed on the surface of one or both sides thereof.

4. The dye-sensitized solar cell according to claim 1, wherein the thickness of the wire rods is greater than the height of the irregularities on the surface of the substrate on which the transparent conductive film and the dye-sensitized semiconductor electrode are formed.

5. The dye-sensitized solar cell according to claim 1, wherein the substrate on which neither the transparent conductive film nor the dye-sensitized semiconductor electrode is formed is insulating.
